(19) United States
(12) Patent Application Publication
(10) Pub. No.: US 2022/0137922 A1
(43) Pub. Date: May 5, 2022

(54) BIT-WIDTH OPTIMIZATION METHOD FOR PERFORMING FLOATING POINT TO FIXED POINT CONVERSION

(71) Applicant: Baum Design Systems Co., Ltd., Seoul (KR)

(72) Inventors: Joon Hwan YI, Seoul (KR); Gi Sik LEE, Yongin-si, Gyeonggi-do (KR); Chang Won CHOI, Seongnam-si (KR)

(21) Appl. No.: 17/476,476

(22) Filed: Sep. 16, 2021

(30) Foreign Application Priority Data
Nov. 2, 2020 (KR) 10-2020-0144814

(51) Int. Cl. G06F 7/483; G06F 7/499; G06F 5/01

(52) U.S. Cl. CPC G06F 7/483; G06F 5/012; G06F 7/49947

(57) ABSTRACT

Provided is a bit-width optimization method for performing floating point to fixed point conversion (FFC) by at least one processor. The bit-width optimization method includes receiving a first floating-point value which represents a minimum value among floating-point values to be converted, receiving a second floating-point value which represents a maximum value among the floating-point values to be converted, receiving a maximum permissible error rate for performing FFC, calculating a minimum bit width of fixed-point notation which satisfies the maximum permissible error rate on the basis of the first floating-point value, the second floating-point value, and the maximum permissible error rate, and calculating a scale factor for FFC on the basis of the second floating-point value and the calculated minimum bit width.

### CROSS-REFERENCE TO RELATED APPLICATION

This application claims priority to and the benefit of Korean Patent Application No. 10-2020-0144814, filed on Nov. 2, 2020, the disclosure of which is incorporated herein by reference in its entirety.

### BACKGROUND

### 1. Field of the Invention

The present disclosure relates to a bit-width optimization method for performing floating point to fixed point conversion (FFC), and more particularly, to a system and method for calculating a minimum bit width of fixed-point notation which satisfies a maximum permissible error rate and calculating a scale factor for FFC.

### 2. Discussion of Related Art

The representations of binary numbers which are mainly used in digital systems may be classified into fixed-point notation and floating-point notation depending on whether a decimal point position for representing a fraction is fixed or not. Here, fixed-point notation refers to a data representation method in which a decimal point position for representing a fraction is fixed at a specific position. On the other hand, floating-point notation may refer to a data representation method in which a real number is approximated in consideration of the range and accuracy. A standard for floating-point notation is defined in Institute of Electrical and Electronics Engineers (IEEE)-754. In IEEE-754, a single-precision floating-point format is frequently used when a bit width is 32 bits, and a double-precision floating-point format is frequently used when a bit width is 64 bits.

In a digital system, numbers may be represented using a fixed point or a floating point, but the accuracy may be degraded due to the restrictions on bit width. In particular, when a number representing a fraction, such as a real number or a rational number, is represented in fixed-point notation, the accuracy may be degraded, and thus, floating-point notation may be used. On the other hand, integers or natural numbers have the same interval, and thus fixed-point notation which is rapidly calculated may be used.

In an algorithm stage, floating-point notation is frequently used because it is possible to represent a wider range of numbers than fixed-point notation. On the other hand, in algorithm design and implementation stages, floating point operations are frequently converted into fixed point operations and used. This is because floating point operations require higher costs than fixed point operations.

### SUMMARY OF THE INVENTION

The present disclosure is directed to providing a bit-width optimization method for performing floating point to fixed point conversion (FFC) and a computer program stored in a recording medium.

The present disclosure may be implemented in various ways including a method and a computer program stored in a readable storage medium.

According to an aspect of the present disclosure, there is provided a bit-width optimization method for performing FFC by at least one processor, the method including receiving a first floating-point value which represents a minimum value among floating-point values to be converted, receiving a second floating-point value which represents a maximum value among the floating-point values to be converted, receiving a maximum permissible error rate for performing FFC, calculating a minimum bit width of fixed-point notation satisfying the maximum permissible error rate on the basis of the first floating-point value, the second floating-point value, and the maximum permissible error rate, and calculating a scale factor for FFC on the basis of the second floating-point value and the calculated minimum bit width.

The minimum bit width (bw) of fixed-point notation may be calculated as

$$bw = ⌈ {log}_{2} ( \frac{{c}_{max}}{{c}_{min}} \times \frac{50}{{pe}_{ffc}} + 1 ) ⌉ or bw = ⌈ {log}_{2} ( \frac{\vert {c}_{max} \vert}{\vert {c}_{min} \vert} \times \frac{100}{{pe}_{ffc}} + 2 ) ⌉$$

where cₘᵢₙ and |cₘᵢₙ| may be the first floating-point value, cₘₐₓ and |cₘₐₓ| may be the second floating-point value, and pe_{ffc} may be the maximum permissible error rate.

The scale factor (sf) may be calculated as

$$sf = \frac{{2}^{bw} - 1}{{c}_{max}} or sf = \frac{{2}^{bw - 1} - 1}{\vert {c}_{max} \vert}$$

where bw may be the minimum bit width of fixed-point notation, cₘₐₓ and |cₘₐₓ| may be the second floating-point value, and pe_{ffc} may be the maximum permissible error rate.

The bit-width optimization method may further include converting one of the floating-point values to be converted into a fixed-point value using the calculated scale factor, and the fixed-point value may be calculated as c_{fixed}=round(c_{float}×sf) where c_{float} may be the one of the floating-point values to be converted, c_{fixed} may be the converted fixed-point value, sf may be the scale factor, and round(x) may be a rounded value of x.

The bit-width optimization method may further include increasing a value of the scale factor so that the scale factor may have the form of 2ⁿ, where n is an integer, and increasing the calculated minimum bit width by one bit so that overflow may not occur due to the increased scale factor.

According to another aspect of the present disclosure, there is provided a bit-width optimization method for performing FFC by at least one processor, the method including receiving a first floating-point value which represents a minimum value among floating-point values to be converted, receiving a second floating-point value which represents a maximum value among the floating-point values to be converted, receiving a maximum permissible error rate for performing FFC, classifying the floating-point values into a plurality of groups on the basis of the first floating-point value and the second floating-point value, calculating a minimum bit width of fixed-point notation, which is applied to the plurality of groups in common and satisfies the maximum permissible error rate, on the basis of the maximum permissible error rate, and calculating a scale factor for each of the plurality of groups on the basis of a maximum floating-point value of the group and the calculated minimum bit width.

Scales of fixed-point values belonging to different groups among the plurality of groups may be made the same through a bit shift operation.

A number (g) of the plurality of groups may be calculated as

$$g = ⌈ - {log}_{2} ( \frac{{c}_{min}}{{c}_{max}} ) \times \frac{1}{m} ⌉$$

where cₘᵢₙ may be the first floating-point value, cₘₐₓ may be the second floating-point value, and m may be a positive integer.

The minimum bit width (bw) of fixed-point notation may be calculated as

$$bw = ⌈ {log}_{2} ( {2}^{m} \times \frac{50}{{pe}_{ffc}} + 1 ) ⌉ or bw = ⌈ {log}_{2} ( {2}^{m} \times \frac{100}{{pe}_{ffc}} + 2 ) ⌉$$

where m may be a positive integer and pe_{ffc} may be the maximum permissible error rate.

The scale factor (sfⱼ) for each of the plurality of groups may be calculated as

$${sf}_{j} = \frac{{2}^{bw} - 1}{{c}_{max , j}} or {sf}_{j} = \frac{{2}^{bw - 1} - 1}{\vert {c}_{max , j} \vert}$$

where sfⱼ may be the scale factor for the j^{th} group among the plurality of groups, j is an integer which is larger than or equal to zero and smaller than or equal to a value obtained by subtracting one from a number g of the plurality of groups (0≤j≤−1), bw may be the minimum bit width of fixed-point notation, c_{max, j} may be a maximum value among floating-point values of the j^{th} group, and |c_{max, j}| may be a maximum value among absolute values of the floating-point values of the j^{th} group.

The bit-width optimization method may further include converting one of the floating-point values to be converted into a fixed-point value using the calculated scale factor, and the fixed-point value may be calculated as c_{fixed}=round(c_{float}×sfⱼ) where c_{float} may be the one of the floating-point values to be converted, c_{fixed} may be the converted fixed-point value, sfⱼ may be the scale factor for the group to which c_{float} belongs, and round(x) may be a rounded value of x.

The bit-width optimization method may further include storing the converted fixed-point value (c_{fixed}) in connection with a group identity (ID) of the floating-point value (c_{float}) to be converted.

The bit-width optimization method may further include increasing a value of the scale factor so that the scale factor has the form of 2ⁿ where n is an integer and increasing the calculated minimum bit width by one bit so that overflow may not occur due to the increased scale factor.

The scale factor (sfⱼ) may be calculated as

$${sf}_{j} = {2}^{⌈ {log}_{2} ( \frac{{2}^{bw - 1}}{\vert {c}_{max , j} \vert} ) ⌉} or {sf}_{j} = {2}^{⌈ {log}_{2} ( \frac{{2}^{bw - {1}_{- 1}}}{\vert {c}_{max , j} \vert} ) ⌉}$$

where sfⱼ may be the scale factor for the j^{th} group among the plurality of groups, j is an integer which is larger than or equal to zero and smaller than or equal to a value obtained by subtracting one from a number g of the plurality of groups (0≤j≤g−1), bw may be the minimum bit width of fixed-point notation, c_{max,j} may be a maximum value among floating-point values of the j^{th} group, and |c_{max,j}| may be a maximum value among absolute values of the floating-point values of the j^{th} group.

According to another aspect of the present disclosure, there is provided a computer program stored in a computer-readable recording medium to perform a bit-width optimization method in a computer.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a diagram illustrating an example of converting a floating-point value into a fixed-point value, inputting the fixed-point value to hardware, and converting a fixed-point value output according to processing of the hardware into a floating-point value according to an exemplary embodiment of the present disclosure;

FIG. 2 is a schematic diagram illustrating a configuration in which an information processing system is communicably connected to a plurality of user terminals to perform bit-width optimization according to an exemplary embodiment of the present disclosure;

FIG. 3 is a block diagram illustrating an internal configuration of the information processing system according to the exemplary embodiment of the present disclosure;

FIG. 4 is a diagram illustrating an example in which the information processing system receives a first floating-point value, a second floating-point value, and a maximum permissible error rate and outputs a minimum bit width and a scale factor according to the exemplary embodiment of the present disclosure;

FIG. 5 is a diagram illustrating an example in which a bit-width calculator and a scale factor calculator calculate a bit width and a scale factor according to an exemplary embodiment of the present disclosure;

FIG. 6 is a diagram illustrating an example in which a data converter converts a floating-point value into a fixed-point value according to an exemplary embodiment of the present disclosure;

FIG. 7 is a diagram illustrating an example in which the information processing system receives a first floating-point value, a second floating-point value, a maximum permissible error rate, and a natural number of m and outputs the number of groups, a minimum bit width, and a scale factor according to the exemplary embodiment of the present disclosure;

FIG. 8 is a diagram illustrating an example in which a grouping module, a bit-width calculator, and a scale factor calculator calculate a minimum bit width and group-specific scale factors according to an exemplary embodiment of the present disclosure;

FIG. 9 is a diagram illustrating an example of classifying a plurality of floating-point values into a plurality of groups according to an exemplary embodiment of the present disclosure;

FIG. 10 is a diagram illustrating an example of storing fixed-point data, which represents a fixed-point value, in connection with a group identity (ID) according to an exemplary embodiment of the present disclosure;

FIG. 11 is a set of diagrams illustrating floating point to fixed point conversion (FFC) results obtained using different scale factors according to an exemplary embodiment of the present disclosure;

FIG. 12 is a flowchart illustrating a bit-width optimization method according to an exemplary embodiment of the present disclosure; and

FIG. 13 is a flowchart illustrating a bit-width optimization method according to another exemplary embodiment of the present disclosure.

### DETAILED DESCRIPTION OF EXEMPLARY EMBODIMENTS

Hereinafter, specific embodiments of the present disclosure will be described in detail with reference to the accompanying drawings. However, in the following descriptions, when a detailed description of a well-known function or configuration may obscure the gist of the present disclosure, the detailed description will be omitted.

In the accompanying drawings, like elements are indicated by like reference numerals. In the following description of embodiments, repeated descriptions of identical or corresponding elements may be omitted. However, even when a description of an element is omitted, such an element is not intended to be excluded from an embodiment.

Terms used herein will be briefly described, and then exemplary embodiments will be described in detail. The terms used herein are selected as general terms which are widely used at present in consideration of functions in the present disclosure but may be altered according to the intent of an engineer skilled in the art, precedents, introduction of new technology, or the like. In addition, specific terms are arbitrarily selected by the applicant and their meanings will be described in detail in the corresponding description of the present disclosure. Therefore, the terms used herein should be defined on the basis of the overall content of the present disclosure instead of simply the names of the terms.

As used herein, the singular forms include the plural forms unless context clearly indicates otherwise. Also, the plural forms include the singular forms unless context clearly indicates otherwise.

When one part is referred to as including an element, this means that the part does not exclude other elements and may include other elements unless specifically described otherwise.

Advantages and features of the disclosed embodiments and implementation methods thereof will be clarified through the following embodiments described with reference to the accompanying drawings. However, the present disclosure may be embodied in different forms and should not be construed as limited to the embodiments set forth herein. Rather, these embodiments are provided so that this disclosure will be thorough and complete and will fully convey the scope of the present disclosure to those of ordinary skill in the art.

In the present specification, a “fixed point” and/or a “fixed-point value” may refer to a number, data, or the like which is represented in fixed-point notation. Also, in the present specification, a “floating point” and/or a “floating-point value” may refer to a number, data or the like which is represented in floating-point notation.

In the present specification, a “minimum of floating-point values” and/or a “minimum fixed-point value” may refer to a smallest value which is not zero among a plurality of floating-point values and/or a smallest value which is not zero among the absolute values of a plurality of floating-point values. Also, in the present specification, a “maximum of floating-point values” and/or a “maximum fixed-point value” may refer to a smallest value among a plurality of floating-point values and/or a largest value among the absolute values of a plurality of floating-point values.

In the present specification, a “maximum value of a group” may refer to a largest value among values belonging to the group and/or a largest value among the absolute values of the values belonging to the group. In the present specification, a “minimum value of a group” may refer to a smallest value excluding zero among values belonging to the group and/or a smallest value excluding zero among the absolute values of the values belonging to the group.

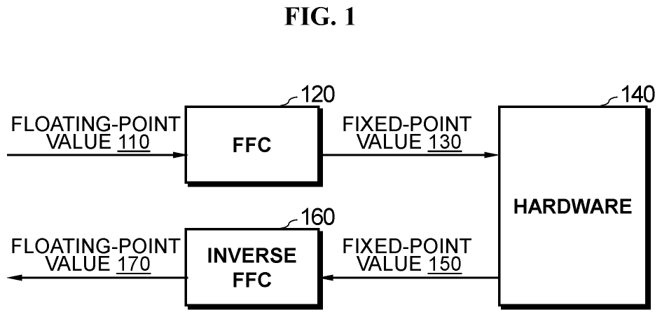

FIG. 1 is a diagram illustrating an example of converting a floating-point value 110 into a fixed-point value 130, inputting the fixed-point value 130 to hardware 140, and converting a fixed-point value 150 output according to processing of the hardware 140 into a floating-point value 170 according to an exemplary embodiment of the present disclosure. Representations of binary numbers which are mainly used in digital systems may be classified into fixed-point notation and floating-point notation depending on whether a decimal point position for representing a fraction is fixed or not. In an algorithm stage for digital system implementation, floating-point notation which may represent a wider range of numbers is frequently used. However, a data calculation stage according to such floating-point notation includes normalization, calculation, rounding, renormalization, exception handling, etc. and thus may require higher costs for performing an arithmetic operation than fixed-point notation. Therefore, in hardware design and implementation stages for digital system implementation, fixed-point notation which requires low calculation costs may be used unlike in the algorithm stage. Also, in the hardware design and implementation stages, it is necessary to design hardware with an optimized bit width, unlike in the algorithm stage. Since required hardware resources are reduced with a smaller bit width, it is possible to reduce costs required for an arithmetic operation by minimizing and/or optimizing a bit width.

In digital system implementation, data processed in the algorithm stage may be used in the hardware stage, or data processed in the hardware stage may be used in the algorithm stage. In other words, it is required to convert a floating-point value processed in the algorithm stage into a fixed-point value which is processible in the hardware stage, and in reverse, it is required to convert a fixed-point value processed in the hardware stage into a floating-point value when necessary.

As shown in the drawing, the floating-point value 110 may be converted into the fixed-point value 130 through a floating point to fixed point conversion (FFC) 120. Here, the floating-point value 110 to be converted may be a process result of a computer program, software, or the like which performs an arithmetic operation using data represented in floating-point notation. Subsequently, the fixed-point value 130 may be input to the hardware 140, and an arithmetic operation may be performed in the hardware 140.

The fixed-point value 150 output as a process result of the hardware 140 may be converted back into the floating-point value 170 through an inverse FFC 160 for an arithmetic operation of the computer program, software, or the like. In such an FFC and an inverse FFC, it is important in terms of cost to minimize and/or optimize a bit width in fixed-point notation while reducing an error caused by data conversion.

FIG. 1 shows the FFC 120 and the inverse FFC 160 for data conversion as separate elements, but the present disclosure is not limited thereto. For example, the FFC 120 and the inverse FFC 160 may correspond to one element which performs both an FFC process and an inverse FFC process. Alternatively, the FFC 120 and the inverse FFC 160 may be separate elements which are connected to each other for communication.

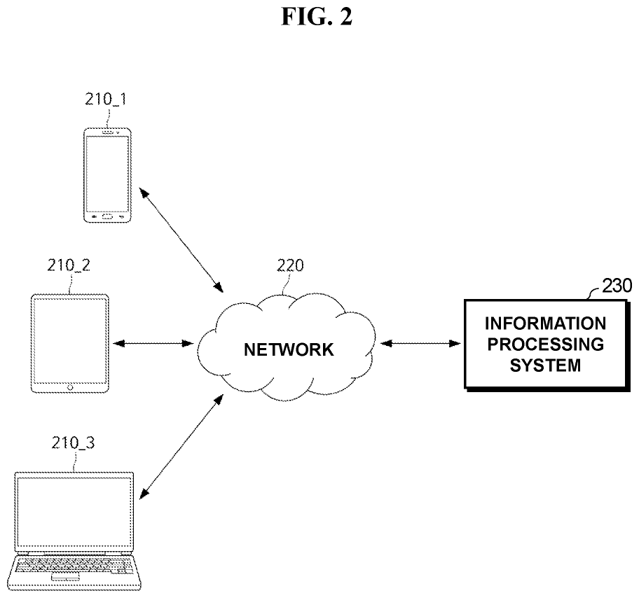

FIG. 2 is a schematic diagram illustrating a configuration in which an information processing system 230 is communicably connected to a plurality of user terminals 210_1, 210_2, and 210_3 to perform bit-width optimization according to an exemplary embodiment of the present disclosure. The information processing system 230 may include a system(s) for providing bit-width optimization.

According to the exemplary embodiment, the information processing system 230 may include one or more server devices and/or databases or one or more cloud computing service-based distributed computing devices and/or distributed databases which may store, provide, and execute computer-executable programs (e.g., a downloadable application) and data related to bit-width optimization. For example, the information processing system 230 may include an additional system (e.g., a server) for providing bit-width optimization.

Bit-width optimization provided by the information processing system 230 may be provided through a bit-width optimization application and the like installed in each of the plurality of user terminals 210_1, 210_2, and 210_3. Alternatively, the user terminals 210_1, 210_2, and 210_3 may perform tasks, such as minimum bit-width calculation, scale factor calculation, and data conversion, using a bit-width optimization program or algorithm installed therein. In this case, the user terminals 210_1, 210_2, and 210_3 may perform tasks, such as minimum bit-width calculation, scale factor calculation, and data conversion, without communication with the information processing system 230.

The plurality of user terminals 210_1, 210_2, and 210_3 may communicate with the information processing system 230 through a network 220. The network 220 may be configured to allow communication between the plurality of user terminals 210_1, 210_2, and 210_3 and the information processing system 230. The network 220 may be configured as a wired network, such as Ethernet, power line communication, a telephone line communication device, and recommendation system (RS) serial communication, a wireless network, such as a mobile communication network, a wireless local area network (WLAN), Wi-Fi, Bluetooth, and ZigBee, or a combination thereof. There is no limitation on the communication method, which may include not only a communication method employing a communication network (e.g., a mobile communication network, a wireless Internet, a wired Internet, a broadcasting network, and a satellite network) which may be included in the network 220 but also short-range wireless communication between the user terminals 210_1, 210_2, and 210_3.

As examples of user terminals, the cellular phone terminal 210_1, the tablet terminal 210_2, and the personal computer (PC) terminal 210_3 are shown in FIG. 2. However, the user terminals 210_1, 210_2, and 210_3 are not limited thereto and may be any computing device capable of wired and/or wireless communication. For example, user terminals may include a smart phone, a cellular phone, a computer, a laptop PC, a personal digital assistant (PDA), a portable multimedia player (PMP), a tablet PC, and the like. Although FIG. 2 shows that the three user terminals 210_1, 210_2, and 210_3 communicate with the information processing system 230 through the network 220, the present disclosure is not limited thereto, and a different number of user terminals may communicate with the information processing system 230 through the network 220.

According to the exemplary embodiment, the information processing system 230 may receive data (e.g., a minimum and maximum of floating-point values to be converted, and a maximum permissible error rate) from the user terminals 210_1, 210_2, and 210_3 through the bit-width optimization application or the like which runs on the user terminals 210_1, 210_2, and 210_3. Subsequently, the information processing system 230 may calculate a minimum bit width of fixed-point notation satisfying the maximum permissible error rate and/or a scale factor for FFC on the basis of the received data and transmit the calculated minimum bit width and/or scale factor to the user terminals 210_1, 210_2, and 210_3.

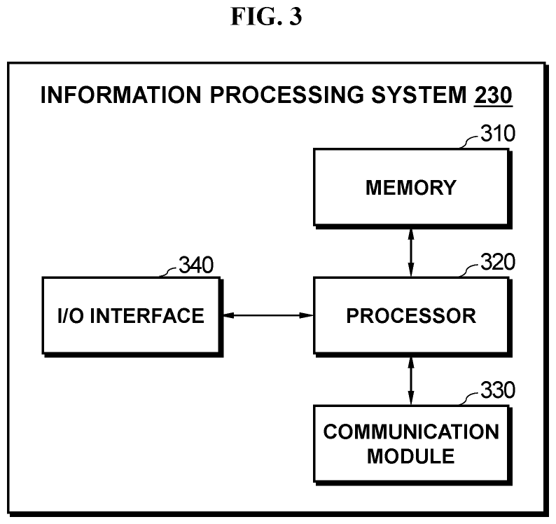

FIG. 3 is a block diagram illustrating an internal configuration of the information processing system 230 according to an exemplary embodiment of the present disclosure. The information processing system 230 may include a memory 310, a processor 320, a communication module 330, and an input/output interface 340. As shown in FIG. 3, the information processing system 230 may be configured to transmit or receive information and/or data through a network using the communication module 330.

The memory 310 may include any non-transitory computer-readable recording medium. According to an exemplary embodiment, the memory 310 may include a permanent mass storage device such as a random access memory (RAM), a read only memory (ROM), a disk drive, a solid state drive (SSD), and a flash memory. As another example, a permanent mass storage device, such as a ROM, an SSD, a flash memory, and a disk drive, may be included in the information processing system 230 as a permanent storage device separate from the memory 310. Also, the memory 310 may store an operating system and at least one program code (e.g., pieces of code for a bit-width optimization application, a scale factor calculation program, a data conversion program, etc. which are installed and run on the information processing system 230).

Such software elements may be loaded from a computer-readable recording medium separate from the memory 310. Such a separate computer-readable recording medium may include a recording medium which may be directly connected to the information processing system 230, for example, a floppy drive, a disk, tape, a digital versatile disk (DVD)/compact disc (CD)-ROM drive, and a memory card. As another example, software elements may be loaded to the memory 310 through the communication module 330 rather than a computer-readable recording medium. For example, at least one program may be loaded to the memory 310 on the basis of a computer program (e.g., a bit-width optimization application, a scale factor calculation program, and a data conversion program) installed with files which are provided through the communication module 330 by developers or a file distribution system for distributing application installation files.

The processor 320 may be configured to process commands of a computer program by performing basic arithmetic, logic, and input/output operations. The commands may be provided to the processor 320 by the memory 310 or the communication module 330. For example, the processor 320 may be configured to execute received commands according to a program code stored in a recording device such as the memory 310.

The communication module 330 may provide a configuration or function for a user terminal (not shown) and the information processing system 230 to communicate with each other through a network and may provide a configuration or function for the information processing system 230 to communicate with another system (e.g., a separate cloud system) through a network. As an example, a control signal, command, data, etc. provided according to control of the processor 320 of the information processing system 230 may pass through the communication module 330 and a network and then may be received by the user terminal through a communication module of the user terminal. For example, the user terminal may receive a minimum bit width of fixed-point notation which satisfies a maximum permissible error rate, a scale factor for FFC, etc. from the information processing system 230.

The input/output interface 340 of the information processing system 230 may be a device for connecting to the information processing system 230 and interfacing with an input or output device (not shown) which may be included in the information processing system 230. Although the input/output interface 340 is shown as a separate element from the processor 320 in FIG. 3, the present disclosure is not limited thereto, and the input/output interface 340 may be included in the processor 320. The information processing system 230 may include more elements than those of FIG. 3. However, it is unnecessary to clearly show most elements of a related art.

The processor 320 of the information processing system 230 may be configured to manage, process, and/or store information and/or data received from a plurality of user terminals and/or a plurality of external systems. According to the exemplary embodiment, the processor 320 may store, process, and transmit a maximum, a minimum, a maximum permissible error rate, etc. of floating-point values to be converted which are received from a user terminal. For example, the processor 320 may calculate a minimum bit width of fixed-point notation which satisfies the maximum permissible error rate on the basis of the maximum and the minimum of the floating-point values to be converted, which are received from a user terminal, and the maximum permissible error rate. In addition, the processor 320 may calculate a scale factor for FFC on the basis of the maximum of the floating-point values to be converted and the minimum bit width.

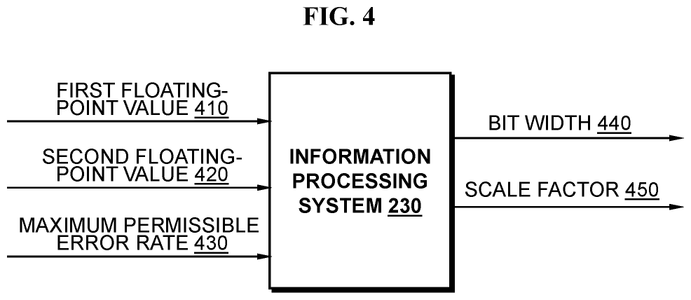

FIG. 4 is a diagram illustrating an example in which the information processing system 230 receives a first floating-point value 410, a second floating-point value 420, and a maximum permissible error rate 430 and outputs a minimum bit width 440 and a scale factor 450 according to the exemplary embodiment of the present disclosure. According to the exemplary embodiment, the information processing system 230 may receive the first floating-point value 410 which represents a minimum of floating-point values to be converted and the second floating-point value 420 which represents a maximum of the floating-point values to be converted. For example, the information processing system 230 may receive a range of floating-point values to be converted and determine the first floating-point value 410 and the second floating-point value 420 on the basis of the received range of floating-point values. Alternatively, the information processing system 230 may receive a plurality of floating-point values to be converted and determine a minimum and a maximum of the received plurality of floating-point values as the first floating-point value 410 and the second floating-point value 420, respectively.

Also, the information processing system 230 may receive the maximum permissible error rate 430 for FFC. Here, the maximum permissible error rate 430 may be set by a user to a maximum permissible value (e.g., 1%, 5%, or 10%) of error rates resulting from data conversion. To reduce an error rate in FFC, it is necessary to increase a bit width of fixed-point notation, and to reduce arithmetic operation costs, it is necessary to reduce a bit width of fixed-point notation. Therefore, the information processing system 230 calculates the minimum bit width 440 of fixed-point notation which satisfies the maximum permissible error rate 430 in order to minimize costs while maintaining performance according to the maximum permissible error rate 430. According to the exemplary embodiment, the information processing system 230 may calculate the minimum bit width 440 of fixed-point notation which satisfies the maximum permissible error rate 430 on the basis of the received first floating-point value 410, second floating-point value 420, and maximum permissible error rate 430.

Subsequently, the information processing system 230 may calculate the scale factor 450 for FFC on the basis of the second floating-point value 420 and the calculated minimum bit width 440. According to the exemplary embodiment, the calculated scale factor 450 is multiplied by a floating-point value to be input to hardware so that the floating-point value may be converted into a fixed-point value. On the other hand, a fixed-point value output from hardware is divided by the scale factor 450 so that the fixed-point value may be converted into a floating-point value.

FIG. 4 shows that the information processing system 230 outputs the minimum bit width 440 and the scale factor 450, but the present disclosure is not limited thereto. For example, the information processing system 230 may output additional data in addition to the minimum bit width 440 and the scale factor 450. Alternatively, the information processing system 230 may not externally output the calculated minimum bit width 440 and may use the minimum bit width 440 to calculate the scale factor 450 therein.

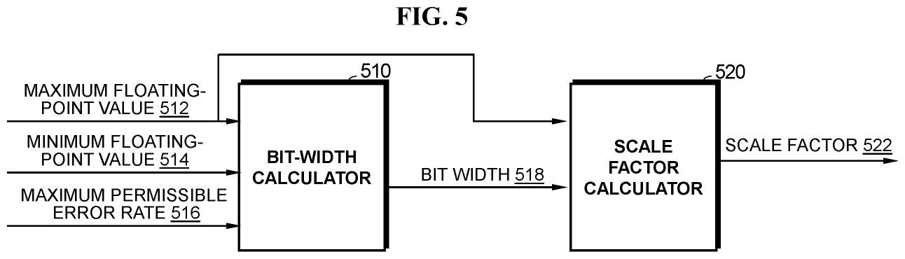

FIG. 5 is a diagram illustrating an example in which a bit-width calculator 510 and a scale factor calculator 520 calculate a minimum bit width 518 and a scale factor 522 according to an exemplary embodiment of the present disclosure. In the exemplary embodiment, an information processing system (e.g., 230 of FIG. 2) may include the bit-width calculator 510 and the scale factor calculator 520. The bit-width calculator 510 may receive a maximum value 512 and a minimum value 514 of floating-point values to be converted and a maximum permissible error rate 516. The bit-width calculator 510 may calculate the minimum bit width 518 of fixed-point notation which prevents an error rate caused by FFC from exceeding the maximum permissible error rate 516, that is, which satisfies the maximum permissible error rate 516. For example, in the case of an unsigned number, the bit-width calculator may calculate the minimum bit width 518 of fixed-point notation which satisfies the maximum permissible error rate 516 according to Equation 1 to Equation 3 below.

$$sf = \frac{{2}^{bw} - 1}{{c}_{max}} \qquad [ Equation 1 ]$$

Here, bw represents a bit width of fixed-point notation, sf represents a scale factor for converting a value represented in floating-point notation into a value having a bit width of bw and represented in fixed-point notation, and cₘₐₓ represents the maximum floating-point value 512. Also, 2^{bw}−1 of Equation 1 may represent the maximum value which may be represented with the bit width of bw, and 1/sf the inverse of sf may represent an interval of numbers with the bit width of bw.

$${pe}_{ffc} \geq {pe}_{max} = \frac{100}{{c}_{min}} {e}_{max} = \frac{100}{{c}_{min}} \frac{1}{2 sf} = \frac{100}{{c}_{min}} \frac{{c}_{max}}{2 \times ( {2}^{bw} - 1 )} = \frac{50 \times {c}_{max}}{( {2}^{bw} - 1 ) \times {c}_{min}} \qquad [ Equation 2 ]$$

Here, pe_{ffc} represents the maximum permissible error rate 516, peₘₐₓ represents a maximum error rate which may occur due to FFC, eₘₐₓ represents a maximum error which may occur due to FFC, cₘᵢₙ represents the minimum floating-point value 514 excluding zero, cₘₐₓ represents the maximum floating-point value 512, and bw represents a bit width of fixed-point notation. As shown in Equation 2, peₘₐₓ may be calculated as an error rate

$$\frac{100}{{c}_{min}} {e}_{max}$$

which may occur with cₘᵢₙ, and eₘₐₓ is a round-off error and thus may be calculated as

$$\frac{1}{2 sf}$$

half an interval of numbers. A minimum value among values of bw satisfying Equation 2, that is, the minimum bit width 518 of fixed-point notation which satisfies the maximum permissible error rate 516, may be calculated according to Equation 3 below.

$${bw}_{min} = ⌈ {log}_{2} ( \frac{{c}_{max}}{{c}_{min}} \times \frac{50}{{pe}_{ffc}} + 1 ) ⌉ \qquad [ Equation 3 ]$$

Here, bwₘᵢₙ represents the minimum bit width 518 of fixed-point notation which satisfies a maximum permissible error rate, cₘᵢₙ represents the minimum floating-point value 514 excluding zero, cₘₐₓ represents the maximum floating-point value 512, and pe_{ffc} represents the maximum permissible error rate 516. ┌x┐ represents an integer value obtained by rounding up x. Since a bit width is a positive integer value, the bit-width calculator 510 may perform such a rounding operation to calculate the minimum bit width 518.

Alternatively, in the case of a signed number, the bit-width calculator 510 may calculate the minimum bit width 518 of fixed-point notation which satisfies the maximum permissible error rate 516 according to Equation 4 to Equation 6 below.

$$sf = \frac{2 ( {2}^{bw - 1} - 1 )}{\vert {c}_{max} \vert - ( - \vert {c}_{max} \vert )} = \frac{{2}^{bw - 1} - 1}{\vert {c}_{max} \vert} \qquad [ Equation 4 ]$$

Here, bw represents a bit width of fixed-point notation, sf represents a scale factor for converting a value represented in floating-point notation into a value having the bit width of bw and represented in fixed-point notation, and |cₘₐₓ| represents the maximum value 512 among absolute values of the floating-point values. A range of numbers which may be represented with the bit width of bw is from −2^{bw-1} to 2^{bw-1}−1. However, to apply the same range of numbers to both negative and positive numbers, sf may be calculated excluding −2^{bw-1}. The inverse of sf,

$$\frac{1}{sf}$$

may represent an interval of numbers with the bit width of bw.

$${pe}_{ffc} \geq {pe}_{max} = \frac{100}{\vert {c}_{min} \vert} {e}_{max} = \frac{100}{\vert {c}_{min} \vert} \frac{1}{2 sf} = \frac{100}{\vert {c}_{min} \vert} \frac{\vert {c}_{max} \vert}{2 \times ( {2}^{bw} - 1 )} = \frac{100 \times \vert {c}_{max} \vert}{( {2}^{bw} - 2 ) \times \vert {c}_{min} \vert} \qquad [ Equation 5 ]$$

Here, pe_{ffc} represents the maximum permissible error rate 516, peₘₐₓ represents a maximum error rate which may occur due to FFC, eₘₐₓ represents a maximum error which may occur due to FFC, cₘᵢₙ represents a minimum among absolute values of the floating-point values excluding zero, |cₘₐₓ| represents a maximum among the absolute values of the floating-point values, and bw represents a bit width of fixed-point notation. peₘₐₓ may be calculated as an error rate

$$\frac{100}{\vert {c}_{min} \vert} {e}_{max}$$

which may occur with |cₘᵢₙ|, and eₘₐₓ is a round-off error and thus may be calculated as

$$\frac{1}{2 sf}$$

half an interval of numbers. A minimum value among values of bw satisfying Equation 5, that is, the minimum bit width 518 of fixed-point notation which satisfies the maximum permissible error rate 516, may be calculated according to Equation 6 below.

$${bw}_{min} = ⌈ {log}_{2} ( \frac{\vert {c}_{max} \vert}{\vert {c}_{min} \vert} \times \frac{100}{{pe}_{ffc}} + 2 ) ⌉ \qquad [ Equation 6 ]$$

Here, bwₘᵢₙ represents the minimum bit width 518 of fixed-point notation which satisfies the maximum permissible error rate, |cₘᵢₙ| represents a minimum value among the absolute values of the floating-point values excluding zero, |cₘₐₓ| represents a maximum value among the absolute values of the floating-point values, and pe_{ffc} represents the maximum permissible error rate 516. ┌x┐ represents an integer value obtained by rounding up x. Since a bit width is a positive integer value, the bit-width calculator 510 may perform such a rounding operation to calculate the minimum bit width 518.

The scale factor calculator 520 may receive the maximum value 512 of the floating-point values to be converted and the minimum bit width 518 calculated by the bit-width calculator 510. The scale factor calculator 520 may calculate the scale factor 522 for FFC on the basis of the received maximum floating-point value 512 and the minimum bit width 518. For example, in the case of an unsigned number, the scale factor calculator 520 may calculate the scale factor 522 by substituting the maximum floating-point value 512 for cₘₐₓ of Equation 1 and substituting the minimum bit width 518 for bw. Alternatively, in the case of a signed number, the scale factor calculator 520 may calculate the scale factor 522 by substituting a maximum value among absolute values of floating-point values for |cₘₐₓ| of Equation 4 and substituting the minimum bit width 518 for bw.

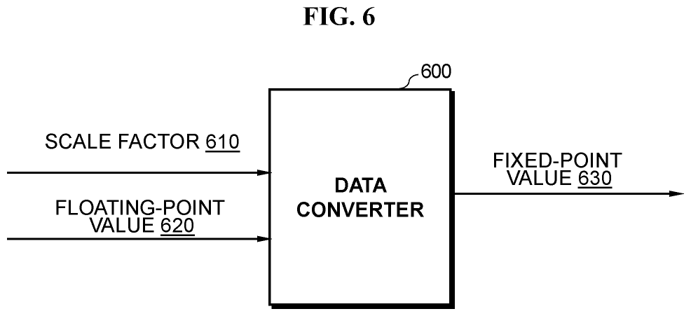

FIG. 6 is a diagram illustrating an example in which a data converter 600 converts a floating-point value 620 into a fixed-point value 630 according to an exemplary embodiment of the present disclosure. In the exemplary embodiment, the data converter 600 may be included in an information processing system (e.g., 230 of FIG. 2). Alternatively, the data converter 600 may not be included in an information processing system and may be configured as a separate system from an information processing system.

As shown in the drawing, the data converter 600 may receive the floating-point value 620 to be converted and a scale factor 610. The data converter 600 may convert the floating-point value 620 into a fixed-point value 630 using the received scale factor 610. For example, the data converter 600 may convert the floating-point value 620 into the fixed-point value 630 according to Equation 7 below.

c_{fixed}=round(c_{float}×sf) [Equation 7]

Here, c_{float} may represent the floating-point value 620 to be converted, c_{fixed} may represent the converted fixed-point value 630, sf may represent the scale factor 610, and round(x) may represent a rounded value of x.

On the other hand, the data converter 600 may convert the fixed-point value 630, which is converted using the scale factor 610, back into a floating-point value. For example, the data converter 600 may convert the converted fixed-point value 630 back into a floating-point value according to Equation 8 below.

$${c}_{float}^{′} = \frac{{c}_{fixed}}{sf} \qquad [ Equation 8 ]$$

Here, c_{fixed} may represent the converted fixed-point value 630, sf may represent the scale factor 610, and c_{float} may represent a converted-back floating-point value. An error rate between the floating-point value 620 to be converted in Equation 7 and the floating-point value converted back in Equation 8 may be calculated according to Equation 9 below.

$${pe}_{{c}_{float}} = \frac{100 \times \vert {c}_{float} - {c}_{float}^{′} \vert}{{c}_{float}} \qquad [ Equation 9 ]$$

Here, c_{float} may represent the floating-point value 620 to be converted, c′_{float} may represent a converted-back floating-point value, and pe_{c}_{_{float}} may represent an error rate resulting from data conversion between floating-point notation and fixed-point notation with respect to c_{float}. When the data converter 600 converts the floating-point value 620 into the fixed-point value 630 using the scale factor 610 which is calculated on the basis of the minimum bit width of fixed-point notation satisfying the maximum permissible error rate, pe_{c}_{_{float}} may be smaller than or equal to the maximum permissible error rate.

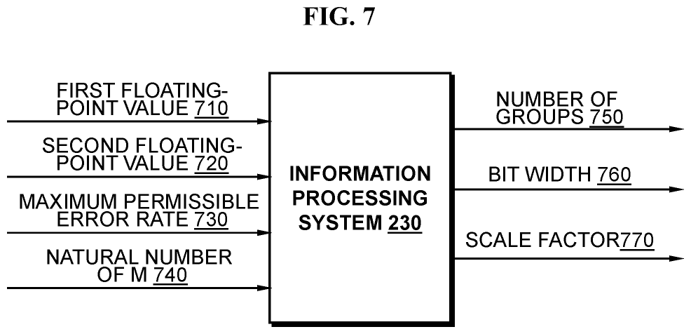

FIG. 7 is a diagram illustrating an example in which the information processing system 230 receives a first floating-point value 710, a second floating-point value 720, a maximum permissible error rate 730, and a natural number 740 of m and outputs a number of groups 750, a minimum bit width 760, and a scale factor 770 according to the exemplary embodiment of the present disclosure. When

$$\frac{{c}_{max}}{{c}_{min}} and / or \frac{\vert {c}_{max} \vert}{\vert {c}_{min} \vert}$$

has a large value in Equation 3 and Equation 6 described above, the calculated minimum bit width bwₘᵢₙ may be large. When the minimum bit width bwₘᵢₙ is calculated to be large, hardware resources required for performing an arithmetic operation may increase, and high costs may be required. Therefore, when

$$\frac{{c}_{max}}{{c}_{min}} and / or \frac{\vert {c}_{max} \vert}{\vert {c}_{min} \vert}$$

has a large value, the information processing system 230 can reduce the minimum bit width of fixed-point notation which satisfies the maximum permissible error rate by classifying floating-point values to be converted into a plurality of groups.

As shown in the drawing, the information processing system 230 may receive the first floating-point value 710 which represents a minimum of the floating-point values to be converted, the second floating-point value 720 which represents a maximum of the floating point values to be converted, the maximum permissible error rate 730, and the natural number 740 of m. In the exemplary embodiment, the information processing system 230 may classify the floating-point values into a plurality of groups on the basis of the received first floating-point value 710 and second floating-point value 720. In this case, the information processing system 230 may apply the minimum bit width 760 of fixed-point notation which satisfies the maximum permissible error rate 730 to the divided plurality of groups in common. In addition, the information processing system 230 may classify the floating-point values into a plurality of groups so that scales of fixed-point values belonging to different groups among the plurality of groups may be made the same through a bit shift operation. Here, the number of groups 750 may be calculated on the basis of the first floating-point value 710, the second floating-point value 720, and the natural number 740 of m.

Subsequently, the information processing system 230 may calculate the minimum bit width 760 of fixed-point notation which satisfies the maximum permissible error rate 730 on the basis of the received maximum permissible error rate 730. The information processing system 230 may calculate the scale factor 770 for FFC with respect to each of the plurality of groups on the basis of the calculated minimum bit width 760 and a maximum floating-point value of the group.

FIG. 7 shows that the information processing system 230 outputs the calculated number of groups 750, minimum bit width 760, and scale factor 770, but the present disclosure is not limited thereto. For example, the information processing system 230 may output additional data in addition to the number of groups 750, the minimum bit width 760, and the scale factor 770. Alternatively, the information processing system 230 may not externally output the calculated number of groups 750 and/or minimum bit width 760 and may use the number of groups 750 and/or the minimum bit width 760 to calculate the scale factor 770 therein.

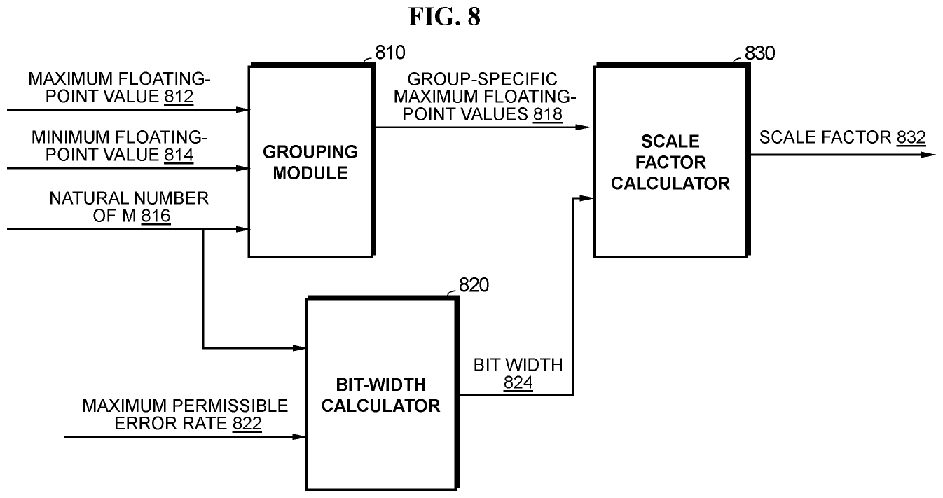

FIG. 8 is a diagram illustrating an example in which a grouping module 810, a bit-width calculator 820, and a scale factor calculator 830 calculate a minimum bit width 824 and group-specific scale factors 832 according to an exemplary embodiment of the present disclosure. In the exemplary embodiment, an information processing system (e.g., 230 of FIG. 2) may include the grouping module 810, the bit-width calculator 820, and the scale factor calculator 830. The grouping module 810 may receive a maximum value 812 and a minimum value 814 of floating-point values to be converted and an arbitrary natural number 816 of m. The grouping module 810 may classify the floating-point values into a plurality of groups on the basis of the received maximum value 812, minimum value 814, and natural number 816 of m. Here, the floating-point values may refer to values between the received maximum value 812 and minimum value 814. For example, the grouping module 810 may divide the floating-point values into a plurality of groups so that a value obtained by dividing a maximum value of each group by a minimum value of the group may become 2^{m}. The divided plurality of groups may have the same minimum bit width 824 of fixed-point notation.

In the exemplary embodiment, the grouping module 810 may calculate the number g of a plurality of groups according to Equation 10 to Equation 12 below. When floating-point values are divided on the basis of the maximum floating-point value 812, a minimum value of a group to which the minimum floating-point value 814 belongs may be represented as 2^{-gm} times the maximum floating-point value 812 and is smaller than or equal to the minimum floating-point value 814. Accordingly, the minimum value of the group to which the minimum floating-point value 814 belongs may be represented by Equation 10 below.

$$\begin{matrix}{c}_{max} {2}^{- gm} \leq {c}_{min} & [ Equation 10 ] \\ gm \geq - {log}_{2} ( \frac{{c}_{min}}{{c}_{max}} ) & [ Equation 11 ] \\ g = ⌈ - {log}_{2} ( \frac{{c}_{min}}{{c}_{max}} ) \times \frac{1}{m} ⌉ & [ Equation 12 ]\end{matrix}$$

In Equation 10 to Equation 12, cₘₐₓ represents the maximum floating-point value 812, cₘᵢₙ represents the minimum floating-point value 814, m represents the arbitrary natural number 816, and g represents the number of the plurality of groups. ┌x┐ represents an integer value obtained by rounding up x. Since the number of groups is a positive integer value, the grouping module 810 may perform such a rounding operation.

The bit-width calculator 820 may receive the natural number 816 of m and a maximum permissible error rate 822 and calculate the minimum bit width 824 of fixed-point notation which satisfies the maximum permissible error rate 822. When values obtained by dividing a maximum value of each group by a minimum value of the group are equal to 2^{m}, the minimum bit width 824 of fixed-point notation which satisfies the maximum permissible error rate 822 is the same for each group. For example, in the case of an unsigned number, the bit-width calculator 820 may calculate the minimum bit width 824 of fixed-point notation which is applied to the plurality of groups in common and satisfies the maximum permissible error rate 822.

$${bw}_{min} = ⌈ {log}_{2} ( {2}^{m} \times \frac{50}{{pe}_{ffc}} + 1 ) ⌉ \qquad [ Equation 13 ]$$

Here, 2^{m} represents a value obtained by dividing a maximum value of each group by a minimum value of the group, pe_{ffc} represents the maximum permissible error rate 822, bwₘᵢₙ represents the minimum bit width 824 of fixed-point notation which satisfies the maximum permissible error rate 822. ┌x┐ represents an integer value obtained by rounding up x. Since a bit width is a positive integer value, the bit-width calculator 820 may perform such a rounding operation to calculate the minimum bit width 824.

Alternatively, in the case of a signed number, the bit-width calculator 820 may calculate the minimum bit width 824 of fixed-point notation which is applied to the plurality of groups in common and satisfies the maximum permissible error rate 822 according to Equation 14 below.

$${bw}_{min} = ⌈ {log}_{2} ( {2}^{m} \times \frac{100}{{pe}_{ffc}} + 2 ) ⌉ \qquad [ Equation 14 ]$$

Here, 2^{m} represents a value obtained by dividing a maximum value among absolute values of floating-point values of each group by a minimum value of the absolute values of floating-point values of the group excluding zero, pe_{ffc} represents the maximum permissible error rate 822, bwₘᵢₙ represents the minimum bit width 824 of fixed-point notation which satisfies the maximum permissible error rate 822. ┌x┐ represents an integer value obtained by rounding up x. Since a bit width is a positive integer value, the bit-width calculator 820 may perform such a rounding operation to calculate the minimum bit width 824.

The scale factor calculator 830 may receive a maximum value of each group, that is, group-specific maximum floating-point values 818, from the grouping module 810 and receive the minimum bit width 824 from the bit-width calculator 820. The scale factor calculator 830 may calculate group-specific scale factors 832, that is, a scale factor for each group, on the basis of the received group-specific maximum floating-point values 818 and the minimum bit width 824. For example, in the case of an unsigned number, the scale factor calculator 830 may calculate the scale factor 832 for each group according to Equation 15 below.

$${sf}_{j} = \frac{{2}^{bw} - 1}{{c}_{max , j}} , 0 \leq j \leq g - 1 \qquad [ Equation 15 ]$$

Here, sfⱼ represents a scale factor for a j^{th} group among the plurality of groups, bw represents the minimum bit width 824 of fixed-point notation which satisfies the maximum permissible error rate 822, c_{max,j} represents a maximum floating-point value of the j^{th} group, and g represents the number of groups. The plurality of groups includes a 0^{th} group to a (g−1)^{th} group.

Alternatively, in the case of a signed number, the scale factor calculator 830 may calculate the scale factor 832 for each group according to Equation 16 below.

$${sf}_{j} = \frac{{2}^{bw - 1} - 1}{\vert {c}_{max , j} \vert} , 0 \leq j \leq g - 1 \qquad [ Equation 16 ]$$

Here, sfⱼ represents a scale factor for a j^{th} group among the plurality of groups, bw represents the minimum bit width 824 of fixed-point notation which satisfies the maximum permissible error rate 822, |c_{max,j}| represents a maximum value among absolute values of floating-point values included in the j^{th} group, and g represents the number of groups. The plurality of groups includes a 0^{th} group to a (g−1)^{th} group.

In the exemplary embodiment, the scale factor calculator 830 may transmit the group-specific scale factors 832 to another element (not shown) of the information processing system 230 and/or a separate data conversion system (not shown). The other element of the information processing system 230 and/or the separate data conversion system may receive the floating-point values to be converted and convert the floating-point values into fixed-point values using the group-specific scale factors 832. For example, the other element of the information processing system 230 and/or the separate data conversion system may calculate a fixed-point value by multiplying a floating-point value by a scale factor for a group to which the floating-point value belongs according to Equation 17 below.

c_{fixed}=round(c_{float}×sfⱼ),0≤j≤g−1 [Equation 17]

Here, c_{float} represents a floating-point value to be converted, c_{fixed} represents a converted fixed-point value, sfⱼ represents a scale factor for a group to which c_{float} belongs, and round(x) represents a rounded value of x.

Alternatively, the other element of the information processing system 230 and/or the separate data conversion system may calculate a fixed-point value by multiplying a floating-point value by a scale factor sf₀ for the 0^{th} group and then performing a shift operation according to Equation 18 below.

c_{fixed}=round(c_{float}×sf₀)<<(j*m),0≤j≤g−1 [Equation 18]

Here c_{float} represents a floating-point value to be converted, c_{fixed} represents a converted fixed-point value, sf₀ represents a scale factor for the 0^{th} group, round(x) represents a rounded value of x, and >>(j*m) represents performing a shift operation to the right by as much as j*m.

FIG. 8 shows that the grouping module 810 receives the natural number 816 of m, but the present disclosure is not limited thereto. For example, the grouping module 810 may receive the number of groups g and calculate the natural number of m on the basis of the received number of groups g and Equations 10 and 11.

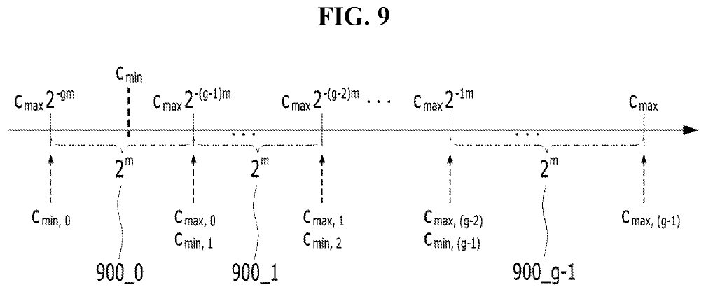

FIG. 9 is a diagram illustrating an example of classifying a plurality of floating-point values into a plurality of groups 900_0, 900_1, . . . , and 900_g−1 according to an exemplary embodiment of the present disclosure. An information processing system (e.g., 230 of FIG. 2) may classify floating-point values to be converted into the plurality of groups 900_0, 900_1, . . . , and 900_g−1 on the basis of a received maximum floating-point value, minimum floating-point value, and natural number of m. Here, the floating-point values to be converted may refer to numbers between the maximum floating-point value and the minimum floating-point value. As shown in FIG. 9, the plurality of groups 900_0, 900_1, . . . , and 900_g−1 may include the 0^{th} group 900_0 to which the minimum floating-point value belongs to the (g−1)^{th} group to which the maximum floating-point value belongs, and g may be the number of groups.

In the exemplary embodiment, the information processing system may classify the floating-point values into the plurality of groups 900_0, 900_1, . . . , and 900_g−1 on the basis of the maximum floating-point value. Specifically, the information processing system may classify the floating-point values into the plurality of groups 900_0, 900_1, . . . , and 900_g−1 so that a value obtained by dividing a maximum value of each group by a minimum value of the group may become 2^{m}. In this case, in order for the plurality of groups 900_0, 900_1, . . . , and 900_g−1 to include all the floating-point values to be converted, a minimum value of the 0^{th} group 900_0 may be made smaller than or equal to a minimum floating-point value to be converted. As shown in the drawing, a maximum floating-point value cₘₐₓ to be converted may become a maximum value c_{max(g-1)} of the (g−1)^{th} group 900_g−1, and a minimum floating-point value cₘᵢₙ to be converted may become greater than or equal to a minimum value c_{min,0} of the 0th group 900_0. Also, a maximum value of an x^{th} group may be equal to a minimum value of an (x+1)^{th} group, and a minimum value of the x^{th} group may be equal to a maximum value of an (x−1)^{th} group. Here, x may be a positive integer of 1 to g−2.

For example, when the minimum floating-point value cₘᵢₙ to be converted is 2⁰=1 and the maximum floating-point value cₘₐₓ to be converted is 2^{2m}, the information processing system may classify the floating-point values into a group (0^{th} group) which has a minimum value c_{min,0} of 2⁰=1 and a maximum value c_{max,0} of 2^{m} and a group (1^{st} group) which has a minimum value c_{min,1} of 2^{m} and a maximum value c_{max,1} of 2^{2m}. In this case, a value

$$\frac{{c}_{max , 0}}{{c}_{min , 0}}$$

obtained by dividing the maximum value of the 0^{th} group by the minimum value of the 0^{th} group and a value

$$\frac{{c}_{max , 1}}{{c}_{min , 1}}$$

obtained by dividing the maximum value of the 1^{st} group by the minimum value of the 1^{st} group are equal to 2^{m}. Therefore, the minimum bit width of the 0^{th} group and the minimum bit width of the 1^{st} group may be calculated according to Equation 19 and Equation 20 below, respectively, and the 0^{th} group and the 1^{st} group have the same minimum bit width of fixed-point notation.

$$\begin{matrix}{bw}_{0} \geq ⌈ {log}_{2} ( \frac{{c}_{max , 0}}{{c}_{min , 0}} \times \frac{50}{{pe}_{ffc}} + 1 ) ⌉ = ⌈ {log}_{2} ( {2}^{m} \times \frac{50}{{pe}_{ffc}} + 1 ) ⌉ & [ Equation 19 ] \\ {bw}_{1} \geq ⌈ {log}_{2} ( \frac{{c}_{max , 1}}{{c}_{min , 1}} \times \frac{50}{{pe}_{ffc}} + 1 ) ⌉ = ⌈ {log}_{2} ( {2}^{m} \times \frac{50}{{pe}_{ffc}} + 1 ) ⌉ & [ Equation 20 ]\end{matrix}$$

Here, c_{max,0} represents the maximum floating-point value of the 0^{th} group, c_{min,0} represents the minimum floating-point value of the 0^{th} group, c_{max,1} represents the maximum floating-point value of the 1^{st} group, c_{min,1} represents the minimum floating-point value of the 1^{st} group, 2^{m} represents a value obtained by dividing a maximum value of each group by a minimum value of the group, pe_{ffc} represents a maximum permissible error rate, bw₀ represents a bit width of the 0^{th} group in fixed-point notation, and bw₁ represents a bit width of the 1^{st} group in fixed-point notation. When floating-point values of 2⁰ to 2^{2m} are not classified into groups, a minimum bit width may be calculated as

$$⌈ {log}_{2} ( {2}^{2 m} \times \frac{50}{{pe}_{ffc}} + 1 ) ⌉$$

according to Equation 3. Therefore, it is possible to see that, when the floating-point values are classified into two groups, a minimum bit width is reduced from about 2m to m in comparison with a case in which the floating-point values are not classified.

Subsequently, according to Equation 15, a scale factor sf₀ for the 0^{th} group may be calculated as

$$\frac{{2}^{{bw}_{0}} - 1}{{c}_{max , 0}} ,$$

and a scale factor sf₁ for the 1^{st} group may be calculated as

$$\frac{{2}^{{bw}_{1}} - 1}{{c}_{max , 1}} .$$

Since the scale factor sf₀ for the 0^{th} group and the scale factor sf₁ for the 1^{st} group satisfy the relationship of Equation 21 below, scales of fixed-point values included in different groups may be made the same through a shift operation.

$$\frac{{sf}_{1}}{{sf}_{0}} = \frac{{c}_{max , 0}}{{c}_{max , 1}} = \frac{1}{{2}^{m}} = {2}^{- m} \qquad [ Equation 21 ]$$

Here, c_{max,0} represents the maximum floating-point value of the 0^{th} group, c_{max,1} represents the maximum floating-point value of the 1^{st} group, 2^{m} represents a value obtained by dividing a maximum value of each group by a minimum value of the group, sf₀ represents the scale factor for the 0^{th} group, and sf₁ represents the scale factor for the 1^{st} group. In this case, a scale of a fixed-point value belonging to the 0^{th} group may be made the same as a scale of a fixed-point value belonging to the 1^{st} group through a left m-bit shift operation. Therefore, scales of converted fixed-point values belonging to different groups among a plurality of groups may be made the same through a bit-shift operation.

As described above, in the case of converting a floating-point value into a fixed-point value using a calculated scale factor for each group, an arithmetic operation can be directly performed on fixed-point values belonging to the same group (i.e., fixed-point values corresponding to floating-point values belonging to the same group) in the hardware stage. In the case of fixed-point values belonging to different groups (i.e., fixed-point values corresponding to floating-point values belonging to different groups), an arithmetic operation can be performed after scales of the floating-point values are made the same through a shift operation. To efficiently use hardware resources, an operation may be performed on numbers belonging to the same group, and then an operation may be performed on numbers belonging to different groups.

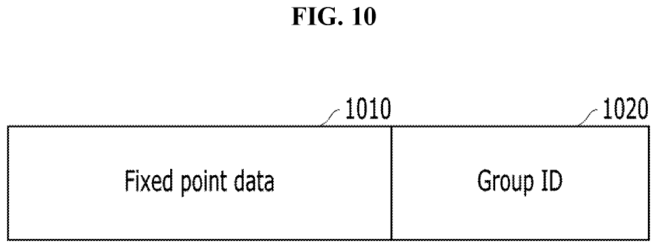

FIG. 10 is a diagram illustrating an example of storing fixed-point data 1010, which represents a fixed-point value, in connection with a group identity (ID) 1020 according to an exemplary embodiment of the present disclosure. In the exemplary embodiment, when a floating-point value is converted into a fixed-point value using a group-specific scale factor which is calculated for each of a plurality of groups, the converted fixed-point value c_{fixed} may be stored in connection with a group ID of the floating-point value c_{float} to be converted. As shown in FIG. 10, the fixed-point data 1010 which represents a converted fixed-point value may be stored in a memory in connection with the group ID 1020. Here, the memory may be a memory of an information processing system (e.g., 230 of FIG. 2) and/or a separate storage device. An overall bit width of data stored in the memory may be calculated as the sum of a bit width of the converted fixed-point value (i.e., a bit width of the fixed-point data 1010) and a bit width of the group ID 1020. An ID of each of the plurality of groups is represented as a binary number, and thus a bit width of the group ID 1020 may be ┌log₂ g┐ (where g is the number of the plurality of groups). Therefore, in the case of an unsigned number, a bit width finally stored in the memory may be calculated as the sum of

$$⌈ {log}_{2} ( {2}^{m} \times \frac{50}{{pe}_{ffc}} + 1 ) ⌉$$

(see Equation 13) which is the bit width of the converted fixed-point value and ┌log₂ g┐ which is the bit width of the group ID 1020. Alternatively, in the case of a signed number, a bit width finally stored in the memory may be calculated as the sum of

$$⌈ {log}_{2} ( {2}^{m} \times \frac{100}{{pe}_{ffc}} + 2 ) ⌉$$

(see Equation 14) which is the bit width of the converted fixed-point value and ┌log₂ g┐ which is the bit width of the group ID 1020. In the case of performing an arithmetic operation on fixed-point values in the hardware stage, after scales of fixed-point values belonging to different groups are made the same through a shift operation according to the group ID 1020, an arithmetic operation may be performed on the fixed-point values.

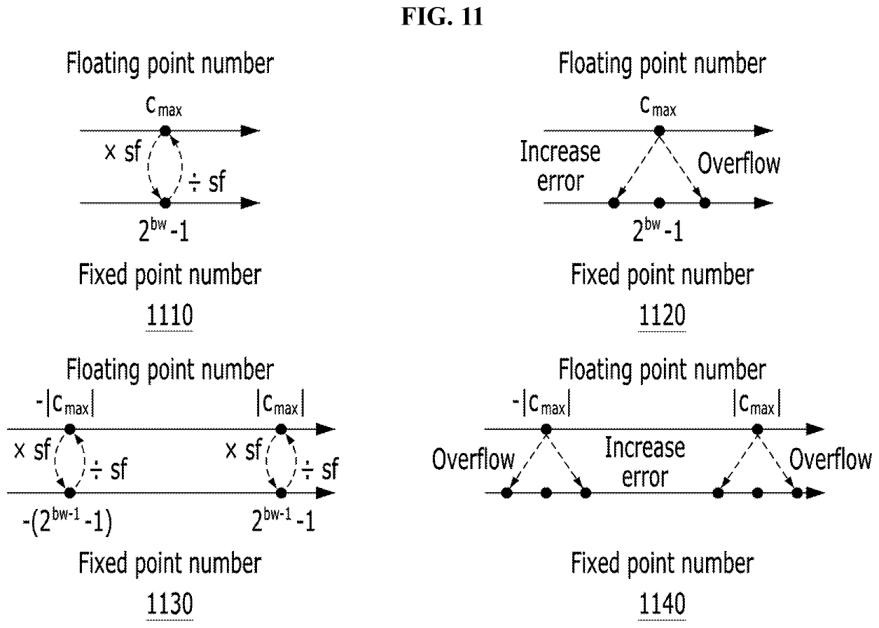

FIG. 11 is a set of diagrams illustrating FFC results 1110, 1120, 1130, and 1140 obtained using different scale factors according to an exemplary embodiment of the present disclosure. The first conversion result 1110 of FIG. 11 shows an example of converting a maximum floating-point value into a fixed-point value using a scale factor which is not increased or reduced when the fixed-point value is an unsigned number, and the second conversion result 1120 shows an example of converting a maximum floating-point value into a fixed-point value using a scale factor which is increased or reduced when the fixed-point value is an unsigned number. The third conversion result 1130 shows an example of converting a maximum value among absolute values of floating-point value into a fixed-point value using a scale factor which is not increased or reduced when the fixed-point value is a signed number, and the fourth conversion result 1140 shows an example of converting a maximum value among absolute values of floating-point value into a fixed-point value using a scale factor which is increased or reduced when the fixed-point value is a signed number. As shown in the first conversion result 1110 and the third conversion result 1130, a floating-point value may be converted into a fixed-point value by multiplying the floating-point value by a scale factor, and in reverse, a fixed-point value may be converted into a floating point value by dividing the fixed-point value by a scale factor.

In the exemplary embodiment, to increase a conversion rate between a floating-point value and a fixed-point value, the information processing system may reduce or increase a scale factor so that the scale factor may have the form of 2ⁿ (where n is an integer). When a scale factor is reduced or increased to have the form of 2ⁿ, a conversion between a floating-point value and a fixed-point value is possible through a shift operation instead of the above-described operation of multiplying or dividing a scale factor, and thus a conversion rate can be increased. As shown in the second conversion result 1120 and the fourth conversion result 1140, when a scale factor is reduced to have the form of 2ⁿ, an error caused by the conversion may increase. On the other hand, when a scale factor is increased to have the form of 2ⁿ, overflow may occur due to the conversion. Therefore, the information processing system may increase a scale factor so that the scale factor may have the form of 2ⁿ and an error caused by the conversion may not be increased. Also, the information processing system may increase the minimum bit width by one bit so that overflow may not occur.

In the exemplary embodiment, when the information processing system classifies floating-point values into a plurality of groups and calculates a scale factor for each group, the scale factor for each group may be increased to have the form of 2ⁿ. For example, in the case of an unsigned number, the information processing system may calculate a final scale factor for each group according to Equation 22 below. Alternatively, in the case of a signed number, the information processing system may calculate a final scale factor for each group according to Equation 23 below.

$$\begin{matrix}{sf}_{j} = {2}^{⌈ {log}_{2} ( \frac{{2}^{bw} - 1}{{c}_{max , j}} ) ⌉} & [ Equation 22 ] \\ {sf}_{j} = {2}^{⌈ {log}_{2} ( \frac{{2}^{bw - 1} - 1}{\vert {c}_{max , j} \vert} ) ⌉} & [ Equation 23 ]\end{matrix}$$

Here, bw represents a minimum bit width of fixed-point notation, c_{max,j} represents a maximum floating-point value of a j^{th} group, |c_{max,j}| represents a maximum value among absolute values of floating-point values of the j^{th} group, and sfⱼ represents a scale factor for the j^{th} group which is increased to have the form of 2ⁿ. j may be an integer of 0 to (the number of groups−1). ┌x┐ represents an integer value obtained by rounding up x, and the information processing system may perform such a rounding operation so that the scale factor may be increased to have the form of 2ⁿ (where n is an integer).

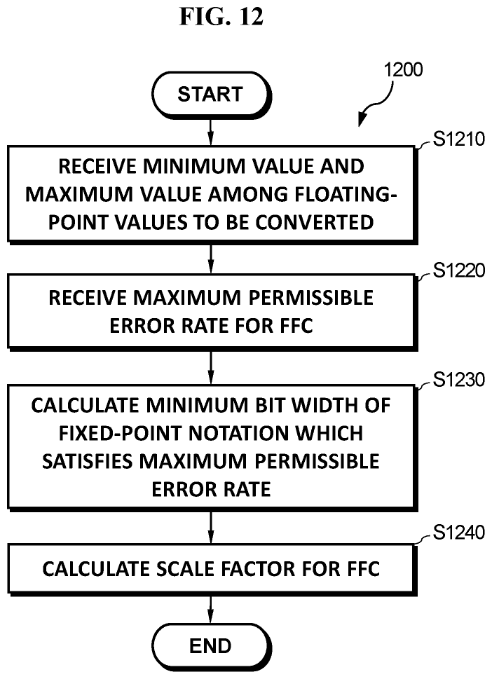

FIG. 12 is a flowchart illustrating a bit-width optimization method 1200 according to an exemplary embodiment of the present disclosure. In the exemplary embodiment, the bit-width optimization method 1200 may be performed by a processor (e.g., at least one processor of an information processing system). As shown in the drawing, the bit-width optimization method 1200 may be started when the processor receives a minimum and a maximum of floating-point values to be converted (S1210). To maintain consistent performance for FFC, the processor may receive a maximum permissible error rate for FFC (S1220).

Subsequently, the processor may calculate a minimum bit width of fixed-point notation which satisfies the maximum permissible error rate on the basis of a first floating-point value which represents the minimum floating-point value, a second floating-point value which represents the maximum floating-point value, and the maximum permissible error rate (S1230). For example, the processor may calculate a minimum bit width of fixed-point notation which satisfies the maximum permissible error rate according to Equation 3 or Equation 6. Subsequently, the processor may calculate a scale factor for FFC on the basis of the second floating-point value and the minimum bit width (S1240). For example, the processor may calculate a scale factor for FFC according to Equation 1 or Equation 4.

In the exemplary embodiment, the processor may increase a value of the scale factor so that the scale factor may have the form of 2ⁿ and may increase the calculated minimum bit width by one bit so that overflow may not occur due to the increased scale factor. Here, n may be an arbitrary integer. In the exemplary embodiment, the processor may convert one of the floating-point values to be converted into a fixed-point value using the calculated scale factor. For example, the processor may convert one of the floating-point values to be converted into a fixed-point value according to Equation 7.

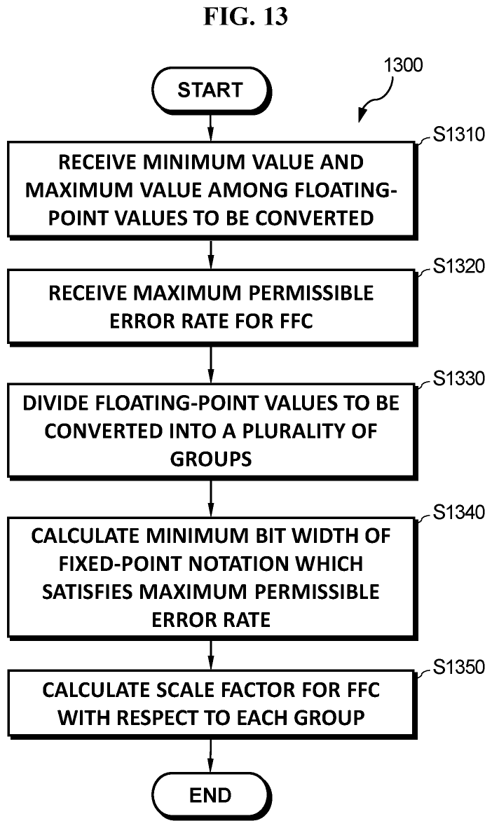

FIG. 13 is a flowchart illustrating a bit-width optimization method 1300 according to another exemplary embodiment of the present disclosure. In the exemplary embodiment, the bit-width optimization method 1300 may be performed by a processor (e.g., at least one processor of an information processing system). As shown in the drawing, the bit-width optimization method 1300 may be started when the processor receives a minimum and a maximum of floating-point values to be converted (S1310). To maintain consistent performance for FFC, the processor may receive a maximum permissible error rate for FFC (S1320).

Subsequently, the processor may classify the floating-point values to be converted into a plurality of groups on the basis of a first floating-point value which represents the minimum floating-point value and a second floating-point value which represents the maximum floating-point value (S1330). Subsequently, the processor may calculate a minimum bit width of fixed-point notation, which is applied to the plurality of groups in common and satisfies the maximum permissible error rate, on the basis of the maximum permissible error rate (S1340). For example, the processor may calculate a minimum bit width of fixed-point notation, which is applied to the plurality of groups in common and satisfies the maximum permissible error rate, according to Equation 13 or Equation 14. Subsequently, the processor may calculate a scale factor for FFC with respect to each group on the basis of the maximum floating-point value of the group and the calculated minimum bit width (S1350). For example, the processor may calculate a scale factor for FFC with respect to each group according to Equation 15 or Equation 16.

In the exemplary embodiment, the processor may increase a value of the scale factor so that the scale factor may have the form of 2ⁿ and may increase the calculated minimum bit width by one bit so that overflow may not occur due to the increased scale factor. Here, n may be an arbitrary integer. For example, the processor may convert the value of the scale factor so that the scale factor may have the form of 2ⁿ according to Equation 22 or Equation 23.

In the exemplary embodiment, the processor may convert one of the floating-point values to be converted into a fixed-point value using the scale factor. For example, the processor may convert one of the floating-point values to be converted into a fixed-point value using the scale factor according to Equation 17 or Equation 18. Scales of fixed-point values belonging to different groups among the plurality of groups may be made the same through a bit shift operation. In the exemplary embodiment, the processor may store the converted fixed-point value c_{fixed} in connection with a group ID of the floating-point value c_{float} to be converted.

According to various exemplary embodiments of the present disclosure, it is possible to calculate a bit width of fixed-point notation and a scale factor for reducing required hardware resources and minimizing costs while an error caused by data conversion does not deviate from a set allowable error range.

According to various exemplary embodiments of the present disclosure, floating-point values to be converted are classified into a plurality of groups, and thus it is possible to further reduce a minimum bit width of fixed-point notation for preventing an error caused by data conversion from deviating from a set allowable error range. Accordingly, resources and costs required for an arithmetic operation in a hardware stage can be reduced.

According to various exemplary embodiments of the present disclosure, in the case of performing an arithmetic operation on fixed-point values belonging to different groups among a plurality of groups, scales are made the same through a shift operation, and then the arithmetic operation can be easily performed. Accordingly, the calculation rate can be increased.

According to various exemplary embodiments of the present disclosure, an FFC (or inverse FFC) operation can be performed through a shift operation instead of a multiplication or division operation, and thus the conversion rate can be increased.

Effects of the present disclosure are not limited to those described above, and other effects which have not been described above will be clearly understood by those of ordinary skill in the art from the claims.

The above-described bit-width optimization methods may be provided as a computer program which is stored in a computer-readable recording medium to perform the methods on a computer. The medium may continuously store a computer-executable program or temporarily store the computer-executable program for execution or downloading. Also, the medium may be various recording means or storage means in the form of a single piece of hardware or a combination of several pieces of hardware. The medium is not limited to a medium directly connected to a specific computer system and may be distributed over a network. Examples of the medium may include a medium configured to store a program instruction, including a magnetic medium, such as a hard disk, a floppy disk, and magnetic tape, an optical recording medium, such as a CD-ROM and a DVD, a magneto-optical medium, such as a floptical disk, a ROM, a RAM, a flash memory, and the like. Further, another example of the medium may include a recording medium or a storage medium managed by an app store for distributing applications or a website, a server, etc. for supplying or distributing various pieces of software.

The methods, operations, or techniques of the present disclosure may be implemented by various means. For example, these techniques may be implemented in hardware, firmware, software, or a combination thereof. Those of ordinary skill in the art will further appreciate that various illustrative logic blocks, modules, circuits, and algorithm steps described in connection with the disclosure herein may be implemented in electronic hardware, computer software, or combinations of both. To clearly describe this interchangeability of hardware and software, various illustrative elements, blocks, modules, circuits, and steps have been generally described above in terms of functionality thereof. Whether such a function is implemented as hardware or software varies depending on design constraints imposed on the particular application and the overall system. Those of ordinary skill in the art may implement the described functions in various ways for each particular application, but such implementation should not be interpreted as causing a departure from the scope of the present disclosure.

In a hardware implementation, processing units used to perform the techniques may be implemented in one or more application-specific integrated circuits (ASICs), digital signal processors (DSPs), digital signal processing devices (DSPDs), programmable logic devices (PLDs), field programmable gate arrays (FPGAs), processors, controllers, microcontrollers, microprocessors, electronic devices, other electronic units designed to perform the functions described herein, a computer, or a combination thereof.

Therefore, various illustrative logic blocks, modules, and circuits described in connection with the present disclosure may be implemented or performed with general-purpose processors, DSPs, ASICs, FPGAs or other programmable logic devices, discrete gate or transistor logic, discrete hardware components, or any combination of those designed to perform the functions described herein. A general purpose processor may be a microprocessor, but in the alternative, the processor may be any existing processor, controller, microcontroller, or state machine. The processor may also be implemented as a combination of computing devices, for example, a DSP and a microprocessor, a plurality of microprocessors, one or more microprocessors associated with a DSP core, or any other combination of such elements.

In a firmware and/or software implementation, the techniques may be implemented with instructions stored in a computer readable medium such as a RAM, a ROM, a non-volatile RAM (NVRAM), a programmable ROM (PROM), an erasable PROM (EPROM), an electrically erasable PROM (EEPROM), a flash memory, a CD, a magnetic or optical data storage device. The instructions may be executable by one or more processors and may cause the processor(s) to perform certain aspects of the functions described in the present disclosure.

Although the above exemplary embodiments have been described as utilizing aspects of the presently disclosed subject matter in the context of one or more standalone computer systems, the subject matter is not limited thereto and may be implemented in conjunction with any computing environment such as a network or distributed computing environment. Further, aspects of the subject matter in the present disclosure may be implemented in or across a plurality of processing chips or devices, and storage may be similarly influenced across a plurality of devices. Such devices may include PCs, network servers, and handheld devices.

Although the present disclosure has been described in connection to some embodiments herein, various modifications and changes can be made without departing from the scope of the present disclosure which can be understood by those of ordinary skill in the technical field to which the present disclosure pertains. Also, such modifications and changes should be considered as falling within the scope of the claims appended herein.

What is claimed is:

1. A bit-width optimization method for performing floating point to fixed point conversion (FFC) by at least one processor, the bit-width optimization method comprising:
receiving a first floating-point value which represents a minimum value among floating-point values to be converted;
receiving a second floating-point value which represents a maximum value among the floating-point values to be converted;
receiving a maximum permissible error rate for performing FFC;
calculating a minimum bit width of fixed-point notation satisfying the maximum permissible error rate on the basis of the first floating-point value, the second floating-point value, and the maximum permissible error rate; and
calculating a scale factor for FFC on the basis of the second floating-point value and the calculated minimum bit width.

2. The bit-width optimization method of claim 1, wherein the minimum bit width (bw) of fixed-point notation is calculated as
$$bw = ⌈ {log}_{2} ( \frac{{c}_{max}}{{c}_{min}} \times \frac{50}{{pe}_{ffc}} + 1 ) ⌉ or bw = ⌈ {log}_{2} ( \frac{\vert {c}_{max} \vert}{\vert {c}_{min} \vert} \times \frac{100}{{pe}_{ffc}} + 2 ) ⌉ ,$$
where cₘᵢₙ and |cₘᵢₙ| are the first floating-point value, cₘₐₓ and |cₘₐₓ| are the second floating-point value, and pe_{ffc} is the maximum permissible error rate.

3. The bit-width optimization method of claim 1, wherein the scale factor (sf) is calculated as
$$sf = \frac{{2}^{bw} - 1}{{c}_{max}} or sf = \frac{{2}^{bw - 1} - 1}{\vert {c}_{max} \vert} ,$$
where bw is the minimum bit width of fixed-point notation, cₘₐₓ and |cₘₐₓ| are the second floating-point value, and pe_{ffc} is the maximum permissible error rate.

4. The bit-width optimization method of claim 1, further comprising converting one of the floating-point values to be converted into a fixed-point value using the calculated scale factor,
wherein the fixed-point value is calculated as c_{fixed}=round(c_{float}×sf),
where c_{float} is the one of the floating-point values to be converted, c_{fixed} is the converted fixed-point value, sf is the scale factor, and round(x) is a rounded value of x.

5. The bit-width optimization method of claim 1, further comprising:
increasing a value of the scale factor so that the scale factor has a form of 2ⁿ, where n is an integer; and
increasing the calculated minimum bit width by one bit so that overflow does not occur due to the increased scale factor.

6. A bit-width optimization method for performing floating point to fixed point conversion (FFC) by at least one processor, the bit-width optimization method comprising:
receiving a first floating-point value which represents a minimum value among floating-point values to be converted;
receiving a second floating-point value which represents a maximum value among the floating-point values to be converted;
receiving a maximum permissible error rate for performing FFC;
classifying the floating-point values into a plurality of groups on the basis of the first floating-point value and the second floating-point value;
calculating a minimum bit width of fixed-point notation, which is applied to the plurality of groups in common and satisfies the maximum permissible error rate, on the basis of the maximum permissible error rate; and
calculating a scale factor for each of the plurality of groups on the basis of a maximum floating-point value of the group and the calculated minimum bit width.

7. The bit-width optimization method of claim 6, wherein scales of fixed-point values belonging to different groups among the plurality of groups are made the same through a bit shift operation.

8. The bit-width optimization method of claim 6, wherein a number (g) of the plurality of groups is calculated as
$$g = ⌈ - {log}_{2} ( \frac{{c}_{min}}{{c}_{max}} ) \times \frac{1}{m} ⌉ ,$$
where cₘᵢₙ is the first floating-point value, cₘₐₓ is the second floating-point value, and m is a positive integer.

9. The bit-width optimization method of claim 6, wherein the minimum bit width (bw) of fixed-point notation is calculated as
$$bw = ⌈ {log}_{2} ( {2}^{m} \times \frac{50}{{pe}_{ffc}} + 1 ) ⌉ or bw = ⌈ {log}_{2} ( {2}^{m} \times \frac{100}{{pe}_{ffc}} + 2 ) ⌉ ,$$
where m is a positive integer and pe_{ffc} is the maximum permissible error rate.

10. The bit-width optimization method of claim 6, wherein the scale factor (sfⱼ) for each of the plurality of groups is calculated as
$${sf}_{j} = \frac{{2}^{bw} - 1}{{c}_{max , j}} or {sf}_{j} = \frac{{2}^{bw - 1} - 1}{\vert {c}_{max , j} \vert} ,$$
where sfⱼ is the scale factor for the j^{th} group among the plurality of groups, j is an integer which is larger than or equal to zero and smaller than or equal to a value obtained by subtracting one from a number g of the plurality of groups (0≤j≤g−1), bw is the minimum bit width of fixed-point notation, c_{max, j} is a maximum value among floating-point values of the j^{th} group, and |c_{max, j}| is a maximum value among absolute values of the floating-point values of the j^{th} group.

11. The bit-width optimization method of claim 6, further comprising converting one of the floating-point values to be converted into a fixed-point value using the calculated scale factor,
wherein the fixed-point value is calculated as c_{fixed}=round(c_{float}×sfⱼ),
where c_{float} is the one of the floating-point values to be converted, c_{fixed} is the converted fixed-point value, sfⱼ is the scale factor for the group to which c_{float} belongs, and round(x) is a rounded value of x.

12. The bit-width optimization method of claim 11, further comprising storing the converted fixed-point value (c_{fixed}) in connection with a group identity (ID) of the floating-point value (c_{float}) to be converted.

13. The bit-width optimization method of claim 6, further comprising:
increasing a value of the scale factor so that the scale factor has a form of 2ⁿ where n is an integer; and
increasing the calculated minimum bit width by one bit so that overflow does not occur due to the increased scale factor.

14. The bit-width optimization method of claim 13, wherein the scale factor (sfⱼ) is calculated as
$${sf}_{j} = {2}^{⌈ {log}_{2} ( \frac{{2}^{bw} - 1}{{c}_{max , j}} ) ⌉} or {sf}_{j} = {2}^{⌈ {log}_{2} ( \frac{{2}^{bw - 1} - 1}{\vert {c}_{max , j} \vert} ) ⌉} ,$$
where sfⱼ is the scale factor for the j^{th} group among the plurality of groups, j is an integer which is larger than or equal to zero and smaller than or equal to a value obtained by subtracting one from a number g of the plurality of groups (0≤j≤g−1), bw is the minimum bit width of fixed-point notation, c_{max, j} is a maximum value among floating-point values of the j^{th} group, and |c_{max, j}| is a maximum value among absolute values of the floating-point values of the j^{th} group.

15. A non-transitory computer-readable storage medium storing instructions that, when executed by a processor, cause the processor to perform the method of claim 1.
